(19) United States
(12) Patent Application Publication
(10) Pub. No.: US 2026/0327783 A1
(43) Pub. Date: Oct. 22, 2026

(54) PROCESS CHAMBER DESIGN TO PREVENT FLUORINE RADICAL REACTIONS

(71) Applicant: Applied Materials, Inc., Santa Clara, CA (US)

(72) Inventors: John J. MAZZOCCO, San Jose, CA (US); Ilya LAVITSKY, San Francisco, CA (US); Keith A. MILLER, Mountain View, CA (US)

(21) Appl. No.: 19/182,215

(22) Filed: Apr. 17, 2025

(51) Int. Cl. C23C 14/34

(52) U.S. Cl. CPC C23C 14/34

(57) ABSTRACT

The present disclosure provides for a process chamber including a process kit that isolates an upper portion of a processing region from a lower portion of the processing region when the process chamber is in a cleaning position. The process kit includes a shield, a plurality of upper ports and lower ports disposed on the surface of the shield, and an adapter plate. The process kit further includes a plurality of delivery plenums and exhaust plenums disposed within the adapter plate and shield. The process kit further includes a plurality of water-cooled plenums within the adapter plate. The process kit further includes an edge including a recess in which a pedestal shield inserts into to form a labyrinth. The process chamber includes a heater ring positioned below and coupled to the process kit and a pedestal disposed in the processing region.

### BACKGROUND

### Field

Embodiments of the present disclosure generally relate to methods and apparatus for improved process chamber cleaning. Specifically, embodiments of the present disclosure relate to methods and apparatus for improved cleaning of physical vapor deposition (PVD).

### Description of the Related Art

During processing of substrates in a process chamber, material is deposited on the substrate. Additionally, during many deposition processes, including PVD, material is also deposited on other areas within the processing region of the process chamber. The material may build up and cause inefficiencies when processing future substrates.

To clean the built up material, a cleaning gas is generally flowed through the processing region. Typically, the cleaning gas includes fluorine. Fluorine is highly reactive, so the fluorine gas reacts with the built up material and removes built up material from the process chamber. The walls of the processing region in which the built up material is deposited onto are often made of compounds or elements that do not readily react with fluorine, or any cleaning gas that is used, and thus, the fluorine cleans the walls without damaging them.

However, in many cases fluorine flows to other areas within the process chamber due to gaps within components or open passages. Thus, fluorine flows to areas in which components are made of materials that readily react with fluorine. Fluorine reacts with these materials and erodes the components, damaging the process chamber. Substantial time and resources are required to replace the eroded components within the process chamber, and the process chamber must stop production during this maintenance and repair.

Additionally, it is not readily detectable when fluorine leaks into other components of the process chamber. This leads to increased damage to the process chamber as the fluorine continues to erode components of the process chamber.

Accordingly, what is needed in the art is a method to prevent fluorine from leaking and flowing to other components of the process chamber that are made of materials which may be readily eroded by fluorine gas. Additionally, what is needed in the art is a method to detect fluorine leakage to prevent continued damage to components of the process chamber.

### SUMMARY

In one embodiment, the present disclosure provides process chambers. The process chambers include a processing region. The processing region is defined by a target and a process kit. The process kit isolates a lower portion of the processing region from an upper portion of the processing region when the process chamber is in a cleaning position. The process kit includes a shield, a plurality of upper ports disposed on the surface of the shield, a plurality of lower ports disposed on the surface of the shield, each lower port positioned below each of the plurality of upper ports, and an adapter plate. The process kit further includes a plurality of delivery plenums disposed within the adapter plate and shield. Each delivery plenum of the plurality of delivery plenums forms a passageway from the adapter plate to one of the plurality of upper ports. The process kit further includes a plurality of exhaust plenums disposed within the adapter plate and shield. Each exhaust plenum of the plurality of exhaust plenums forms a passageway from one of the plurality of lower ports to the adapter plate. The process kit further includes a plurality of water-cooled plenums within the adapter plate. Each of the water-cooled plenums is adjacent to the plurality of exhaust plenums and the plurality of delivery plenums. The process kit further includes an edge including a recess in which a pedestal shield inserts into to form a labyrinth. The process chamber includes a heater ring positioned below and coupled to the process kit. The process chamber further includes a pedestal disposed in the processing region. The pedestal includes the pedestal shield.

In one embodiment, the present disclosure provides process chambers. The process chambers include a remote plasma source for generating a plasma and a processing region. The processing region includes a pedestal, a pedestal shield, and a process kit defining an upper portion of the processing region and isolating the upper portion of the processing region from a lower portion of the processing region when the pedestal is in a cleaning position. The process kit includes a shield, the pedestal shield, a shutter disk, and one or more adapter plates. The process chamber includes a plurality of remote plasma source delivery plenums coupled to the remote plasma source. The plurality of remote plasma source delivery plenums is configured to deliver the plasma to the processing region. The process chamber includes a target comprising a material to be deposited on a substrate disposed on the pedestal. The substrate is positioned in the upper portion of the processing region. The process chamber includes an upper pump fluidly coupled to the upper portion of the processing region and isolated from the lower portion of the processing region when the pedestal is in a cleaning position. The process chamber further includes a lower pump fluidly coupled to the lower portion of the processing region and isolated from the upper portion of the processing region when the pedestal is in the cleaning position.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1A illustrates a schematic, side view of a process chamber with a lid in a closed position, according to one or more embodiments.

FIG. 1B illustrates a schematic, cross-sectional view of a connection between a remote plasma source delivery plenum and a lid coupling device, according to one or more embodiments.

FIG. 1C illustrates a schematic, cross-sectional view of a corner of a remote plasma source delivery plenum, according to one or more embodiments.

FIG. 2 illustrates a schematic, cross-sectional view of a processing region of a process chamber with a shutter disk in an activated position, according to one or more embodiments.

FIG. 3 illustrates an angled, schematic, cross-sectional view of a processing region, delivery plenums, and exhaust plenums of a process chamber, according to one or more embodiments.

FIG. 4 illustrates a top view of a bottom adapter plate, according to one or more embodiments.

FIG. 5 illustrates a top view of an upper adapter plate, according to one or more embodiments.

FIG. 6 illustrates a top view of a middle adapter plate, according to one or more embodiments.

FIG. 7 illustrates a schematic, cross-sectional view of a processing region, delivery plenums, and exhaust plenums of a process chamber, according to one or more embodiments.

FIG. 8A illustrates a schematic, cross-sectional view of a processing region, wherein a labyrinth is in a cleaning position, according to one or more embodiments.

FIG. 8B illustrates a schematic, cross-sectional view of a processing region, wherein a labyrinth is in a minimum deposition position, according to one or more embodiments.

FIG. 8C illustrates a schematic, cross-sectional view of a processing region, wherein a labyrinth is in a maximum deposition position, according to one or more embodiments.

FIG. 9 illustrates a flow diagram of a method of cleaning a process chamber, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to methods and apparatus for improved cleaning of a process chamber. Specifically, embodiments of the present disclosure relate to cleaning physical vapor deposition (PVD) chambers.

Additionally, embodiments described herein may include flowing fluorine gas to clean the chamber. Embodiments described herein may include apparatuses, devices, or methods to prevent the leakage of fluorine gas used to clean the chamber as well as methods to direct and control where the fluorine cleans.

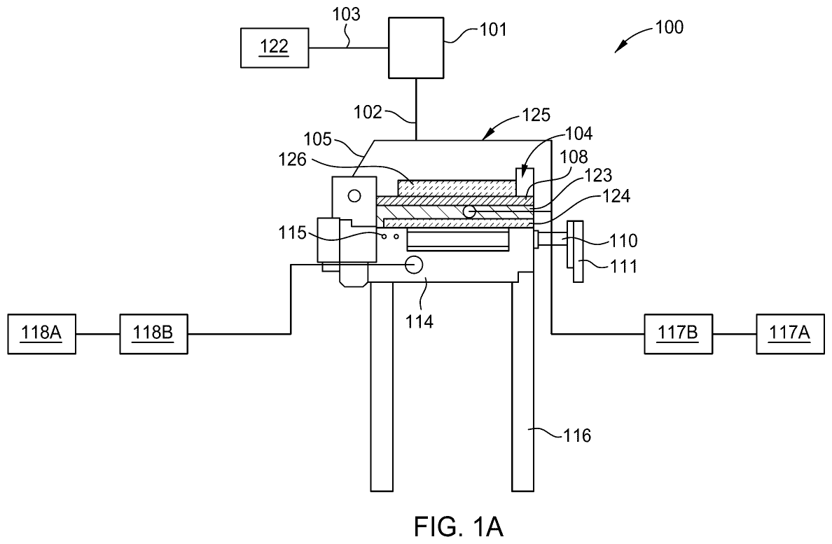

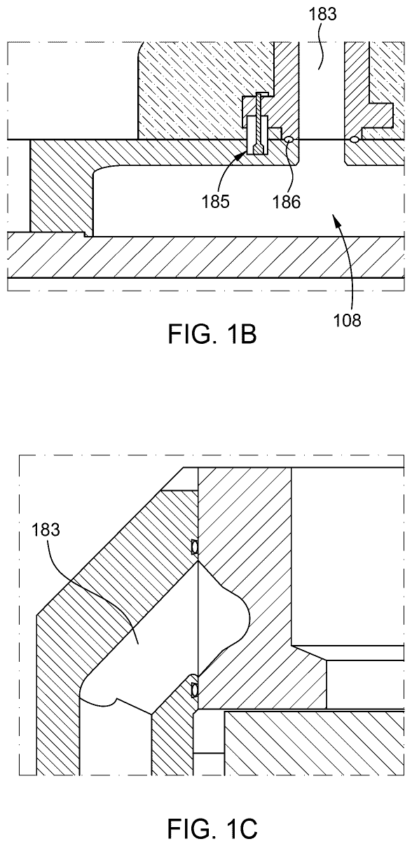

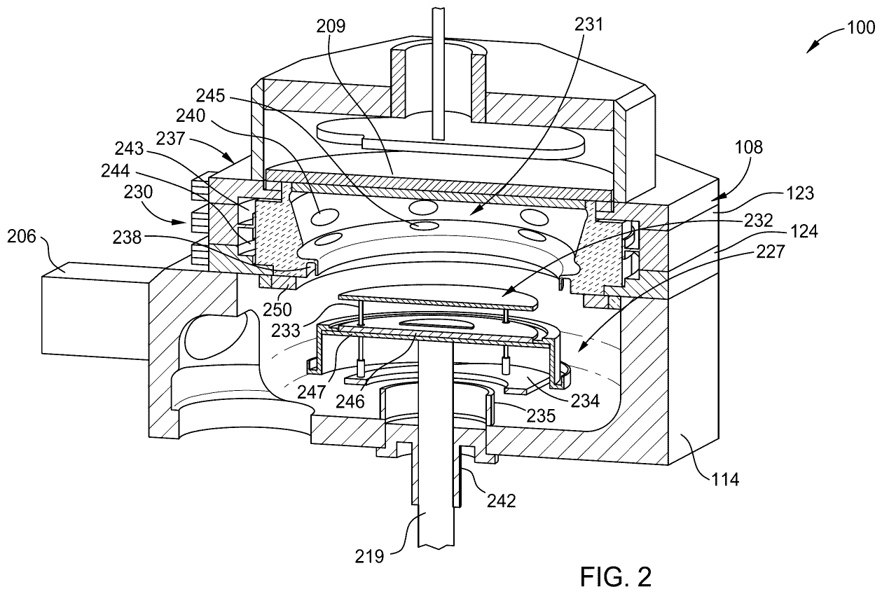

FIG. 1A illustrates a schematic, side view of a process chamber 100 with a lid 125 in a closed position, according to one or more embodiments. The process chamber 100 may be a PVD chamber. The process chamber 100 includes a process gas line 103 which delivers one or more process gases from a process gas supply 122 during a processing operation or one or more cleaning gases during a cleaning operation to a remote plasma source 101. In some embodiments, the cleaning gas delivered includes nitrogen trifluoride (NF₃) or any other compound that includes fluorine. The remote plasma source 101 excites the one or more process gases or cleaning gases into a plasma state. The remote plasma source 101 may be powered by a power supply 104 coupled thereto. The power supply 104 may include a direct current power source or an alternating current power source. In some embodiments in which NF₃ or a fluorine containing compound is utilized, the process of creating plasma generates radical fluorine atoms. The radical fluorine atoms are highly reactive, which increases the ability for the fluorine to clean the process chamber 100 during a cleaning process. These radical fluorine atoms are delivered to a processing region 227 (FIG. 2) of the process chamber 100 through a plurality of remote plasma source delivery tubes 102.

A combination of the remote plasma source 101, remote plasma source delivery tubes 102, and power supply 104 may be coupled to one another via the lid 125 of the process chamber 100. The remote plasma source delivery tubes 102 may be made of any suitable material including, but not limited to, aluminum.

The lid 125 includes a target 209 (FIG. 2) and a magnet coupled to the target 209 for deposition. In some embodiments, the deposition includes physical vapor deposition. The target 209 may be made of any suitable material which is desired to be deposited on a substrate in the processing region 227. In some embodiments, the target 209 is made of silicon. In some embodiments, an argon gas may be delivered to the remote plasma source 101. The argon gas then becomes excited and forms a plasma. The argon plasma is delivered to the processing region 227 and performs a sputter deposition in which the argon plasma contacts the target 209 to eject material from the target 209 onto a substrate placed in the processing region 227 of the process chamber 100.

In some embodiments including a target 209 made of silicon, nitrogen is delivered to the processing region 227 to form a silicon nitride layer over a substrate. In these embodiments, the nitrogen reacts with the silicon target 209 to form silicon nitride in a process of reactive sputtering.

The lid 125 may be coupled to the process chamber 100 via a lid suspension 105 to increase serviceability of the interior processing region 227 of the process chamber 100. The lid suspension 105 may include hinges such that the lid 125 remains coupled to the process chamber 100 but exposes the processing region 227. In some embodiments, the lid 125 hinges at the lid suspension 125 at an angle from 160 to 180 degrees. In some embodiments, the lid 125 is detachable from the process chamber 100 such that it may be removed for servicing the processing region 227 of the process chamber 100.

When the lid 125 is in the closed position, the processing region 227 is not exposed as shown. When the lid 125 is in the open position, the processing region 227 is exposed. In the open position, the processing region 227 is accessible for servicing.

The remote plasma source 101 is positioned above the lid 125 and is coupled to the lid 125, such that the shortest delivery distance of plasma to the processing region 227 is achieved while still being close enough to the source of the plasma. This also allows for increased serviceability of the processing region 227. The remote plasma source 101 is positioned far enough away from the target 209 to increase the ease of opening the lid 125. Additionally, the remote plasma source 101 is positioned close enough to the target 209 such that a large fraction of a reactive species generated from the remote plasma source 101 can be delivered to the processing region 227 without reacting along the way.

A reactive species source is introduced into the remote plasma source 101. In some embodiments, the reactive species source is nitrogen trifluoride. In the remote plasma source 101, the nitrogen trifluoride is cracked such that fluorine radicals are produced. The fluorine radicals are the reactive cleaning species used to clean surfaces of the process chamber 100.

The remote plasma source delivery tubes 102 are symmetrically coupled to the remote plasma source 101 so that the plasma is uniformly delivered to the processing region 227. Uniform delivery of plasma enhances the uniformity of cleaning in the processing region 227 and ultimately results in commercial benefit by reducing the time required to effectively clean the chamber.

The processing region 227 is defined by a chamber body 114. The chamber body 114 may be made of any suitable material. In some embodiments, the chamber body 114 is made of aluminum. The chamber body 114 may be any suitable size for performing a PVD process.

The chamber body 114 is coupled to a choke plate 111 via a tunnel 110. In some embodiments, the choke plate 111 may be a thermal choke plate. The choke plate 111 may be used to insert and remove substrates to and from the processing region 227. The choke plate 111 may further serve as a device to limit air flow to the processing region 227. The chamber body 114 may further include a plurality of chamber body gas inlets 115. The chamber body gas inlets 115 serve as connections to deliver gases from the remote plasma source 101 to the processing region 227. In some embodiments, the cleaning gases delivered include nitrogen trifluoride and any other suitable fluorine containing compounds.

The chamber body 114 may be vertically moved via a plurality of chamber lifting mechanisms 116. In some embodiments, each of the plurality of chamber lifting mechanisms 116 is coupled to a corner of the chamber body 114. The plurality of chamber lifting mechanisms 116 may act dependently on one another such that each chamber lifting mechanism 116 lifts the chamber body 114 the same amount. Alternatively, the plurality of chamber lifting mechanisms 116 may act independently of one another such that each chamber lifting mechanism 116 may lift the chamber body 114 a different amount causing the chamber body 114 to tilt towards or away from one or more of the corners. The process chamber 114 may include a supplemental chamber lifting mechanism which may lift other components coupled to the chamber body 114.

The chamber body 114 includes one or more upper pumps 117 and one or more lower pumps 118. In some embodiments, one or more of the upper pumps 117 includes a rough pump or a turbo pump. A rough pump is a pump that operates up to 100 mTorr. In some embodiments, one or more of the lower pumps 118 includes a turbo pump. A turbo pump is a pump that operates from 1×10⁻⁸ mTorr to 100 mTorr.

In some embodiments, two or more upper pumps 117 are coupled to one another in series. In some embodiments, two or more lower pumps 118 are coupled to one another in series. For example, the first lower pump 118A may be a rough pump that lowers the pressure from a high pressure to a low pressure. Then, the second lower pump 118B may be a turbo pump which lowers the low pressure even further. Without the pumps operating in series, the turbo pump could not lower the temperature to the lower pressure without the assistance of the rough pump to first lower the pressure.

The chamber body 114 is distinct from the lid 125 of the process chamber 100. The chamber body 114 is coupled to the lid 125 via a lid coupling device 126. The lid coupling device 126 is disposed over a plurality of adapter plates (i.e., an upper adapter plate 108, a middle adapter plate 123, and a lower adapter plate 124). An end of each of the plurality of remote plasma source delivery tubes 102 connects to the lid coupling device 126.

FIG. 1B illustrates a schematic, cross-sectional view of a connection between the remote plasma source delivery tube 102 and the lid coupling device 126, according to one or more embodiments. The lid coupling device 126 and remote plasma source delivery tube 102 connect via a removable pin assembly 185. Further, a bumper protrusion 186 is positioned adjacent to the removable pin assembly 185 to allow the removable pin assembly 185 to undergo temperature stresses while still creating a tight seal. The bumper protrusion 186 may be made of a polymer material that may conform to expansions and contractions within the process chamber 100. The remote plasma source delivery tube 102 is coupled to the lid coupling device 126 so that plasma delivered from the remote plasma source 101 may travel through a remote plasma source delivery plenum 183 of the remote plasma source delivery tube 102 to the processing region 227 via the upper plate adapter 108.

FIG. 1C illustrates a schematic, cross-sectional view of a corner of the remote plasma source delivery plenum 183, according to one or more embodiments. The remote plasma source delivery plenum 183 has curved edges to prevent the gas or plasma from reacting with the material on the surface of the remote plasma source delivery plenum 183. When the gas or plasma contacts and reacts with the edges of the remote plasma source delivery plenum 183, the gas or plasma may corrode away the material of the remote plasma source delivery plenum 183 or the gas or plasma may react with the material to build up a material that could cause a blockage in the delivery of the gas or plasma. Either of these issues result in the need for maintenance and decreased efficiency.

The curved angle in the remote plasma source delivery plenum 183 may be achieved by any suitable means including, but not limited to, ball milling, chamfering, and beveling the edge of the remote plasma source delivery plenum 183. The increased curvature of the remote plasma source delivery plenum 183 decreases the gas or plasma losses that result from reacting with the material on the edges. When the angle of an edge is greater than 30 degrees, the gas or plasma flowing through the remote plasma source delivery plenum 183 is more likely to contact the wall of the remote plasma source delivery plenum 183. Accordingly, the radius of curvature of these sharper edges is increased to provide a more gradual turn for the gas or plasma to flow through the remote plasma source delivery plenum 183.

It should be appreciated that the same method of smoothing the sharp edges of the remote plasma source delivery plenum 183 may be equally applied to other plenums described herein to prevent gas or plasma from being lost to reactions with the edges of the plenums.

FIG. 1A further illustrates the plurality of adapter plates 108, 123, 124 disposed over an upper surface of the chamber body 114. The lower adapter plate 124 is disposed over the upper surface of the chamber body 114. The middle adapter plate 123 is disposed over an upper surface of the lower adapter plate 124. In some embodiments, more than one middle adapter plate 123 is included. In such embodiments, the lowest middle adapter plate 123 is disposed over the lower adapter plate 124. Each successive middle adapter plate 123 is disposed over the previous middle adapter plate 123.

The upper adapter plate 108 is disposed over an upper surface of the middle adapter plate 123 and disposed beneath the lid coupling device 126. Each of the plurality of adapter plates 108, 123, 124 includes a central opening defining the processing region 227. The upper adapter plate 108 includes grooves surrounding the central opening, such that the target 209 may be disposed therein and create a tight seal. The grooves surrounding the central opening may include an O-ring disposed therein to improve the seal between the upper adapter plate 108 and the target 209 to prevent the transfer of liquids, gases, or plasma between the processing region 227 and the external environment surrounding the process chamber 100.

FIG. 2 illustrates a schematic, cross-sectional view of the processing region 227 of the process chamber 100 with a shutter disk 232 in an activated position, according to one or more embodiments. The processing region 227 of the process chamber 100 is defined by the chamber body 114 and a process kit 237. The process kit 237 includes a shield 231, the plurality of adapter plates 108, 123, 124, and a process kit edge 238 defining a recess in the bottom surface of the process kit 237. The process kit 237 further includes a plurality of delivery plenums 243 disposed within the upper adapter plate 108, the middle adapter plate 123, and the shield 231. Each of the plurality of delivery plenums 243 forms a passageway from the upper adapter plate 108 to one of a plurality of upper ports 240. The process kit 237 further includes a plurality of exhaust plenums 244 disposed within the lower adapter plate 124, middle adapter plate 123, and the shield 231. Each of the plurality of exhaust plenums 244 forms a passageway from one of the plurality of lower ports 245 to the lower adapter plate 124.

The shield 231 is configured within the process chamber 100 and process kit 237 such that there are gaps between the shield 231 and other components of the process chamber 100 and process kit 237. The shield 231 is spaced away from the other components such that there is adequate space for the shield 231 to thermally expand as it is heated. This gap helps keep the temperature of the shield 231 constant and assists in minimizing the heat transfer from the shield 231 to other components of the process chamber 100 and process kit 237.

In some embodiments, the shield 231 is configured to be radially spaced from about 1 to about 2 millimeters away from the plurality of adapter plates, 108, 123, 124 when the temperature of the pedestal is less than about 350 degrees Celsius. In some embodiments, the shield 231 is configured to be radially spaced from about 1 to about 2 millimeters away from the target 209 and the target outer edge 773 when the temperature of the pedestal is less than about 350 degrees Celsius.

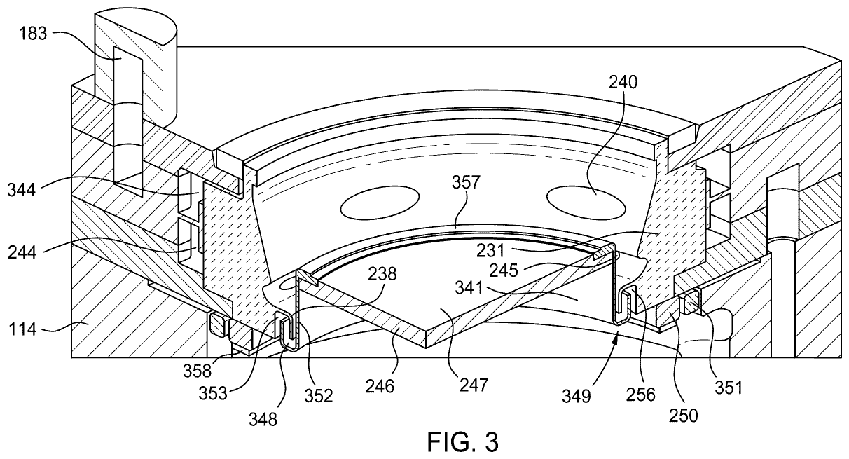

The shield 231 is circumscribed by the plurality of adapter plates 108, 123, 124. The shield 231 may be made of any suitable material. In some embodiments, the shield 231 is made of aluminum. The shield 231 includes the plurality of upper ports 240 and the plurality of lower ports 245 disposed on the surface of the shield 231 exposed to the processing region 227. In some embodiments, the plurality of lower ports 245 are positioned below the plurality of upper ports 240 as shown in FIG. 3.

In some embodiments, the plurality of upper ports 240 deliver a cleaning gas to the processing region 227 and the plurality of lower ports 245 remove the cleaning gas from the processing region 227. In some embodiments, the plurality of lower ports 245 deliver a cleaning gas to the processing region 227 and the plurality of upper ports 240 remove the cleaning gas from the processing region 227.

In some embodiments, the plurality of upper ports 240 are positioned in substantially the same plane as the plurality of lower ports 245. In some embodiments, the plurality of upper ports 240 and the plurality of lower ports 245 are disposed on one portion of the surface of the shield 231 and the other portion of the surface of the shield 231 does not any upper ports 240 or lower ports 245 disposed thereon.

In some embodiments, each of the plurality of upper ports 240 are positioned directly above a corresponding lower port 245. In some embodiments, each of the plurality of upper ports 240 are positioned between two lower ports 245.

The shield 231 surrounds a pedestal 247. The pedestal 247 can support a substrate during processing. The pedestal 247 may be made of any suitable material. In some embodiments, the pedestal 247 is made of a ceramic material. The pedestal 247 may be any size suitable for processing a particularly sized substrate. In some embodiments, the pedestal 247 is of a sufficient size to support a 300 mm substrate.

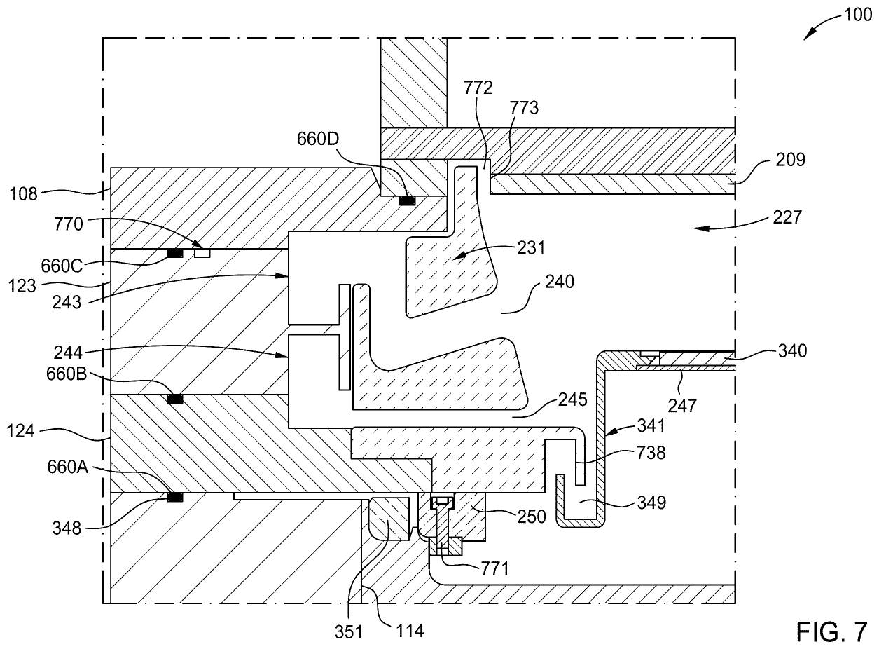

The shield 231 is coupled to a heater ring 250. The heater ring 250 is positioned below the shield 231 in the processing region 227. The heater ring 250 is coupled to a heater controller 206 positioned on the exterior of the process chamber 100, such that the temperature may be easily adjusted during operation. The heater ring 250 may be made of any suitable material that has high temperature resistance and high stress resistance due to the high temperatures and high pressures of the deposition and cleaning processes occurring in the process chamber 100. In some embodiments, the heater ring 250 is made of a nickel alloy or aluminum. In some embodiments, a substrate of the heater ring 250 is made of a nickel alloy or aluminum. In some embodiments, a heating element of the heater ring 250 is made of a nickel alloy. In some embodiments the heater ring 250 is coupled to the bottom surface of the shield 231 via one or more heater ring lift pins 771 (shown in FIG. 7).

In some embodiments, a heating element of the heater ring 250 is enclosed on three sides to prevent any cleaning gas from reacting with the heating element of the heater ring 250. In these embodiments, the heating element of the heater ring 250 may directly contact the surface of the shield 231 to increase the heat transfer from the heating element to the shield 231.

It should be appreciated that other embodiments may be implemented that can heat the shield 231 without heating other elements of the process chamber 100, including, but not limited to, the shutter disk 232. The shield 231 is separately heated from other elements of the process chamber 100, such as the shutter disk 232, to increase the reaction selectivity in the shield 231. Fluorine and other cleaning gas plasma more readily reacts with compounds and elements at a higher temperature, rather than lower temperatures. Often more deposited material is built up on the shield 231 rather than other components such as the shutter disk 232. Accordingly, the shield 231 is heated to a higher temperature so that fluorine more readily reacts with the deposited material on the shield 231 rather than another component of the process chamber 100.

In some embodiments, the heater ring 250 may be segmented, such that each segment has its own heating element that may be heated to a temperature independent of the heating elements of the other segments of the heater ring 250. Each segment of the heater ring 250 corresponds to a section of the shield 231. Accordingly, multiple sections of the shield 231 may each be heated to different temperatures, such that the reaction selectivity varies across the shield 231. Controlling the temperature, and accordingly the reaction site selectivity of segments of the shield 231, may be useful when a pattern of deposition material build up is noticed after processing a batch of substrates. An operator of the process chamber 100 may observe a deposition material build up in certain sections rather than others. In response, different segments of the heater ring 250 may be variably heated such that the sections of the shield 231 with greater deposition material build up have an increased temperature in comparison to other sections of the shield 231.

In embodiments in which the heater ring 250 is segmented, insulated material may be deposited between each segment of the heater ring 250. The segments may be of equal arc length or may be of different arc lengths. For example, the heater ring 250 may be divided into four equal segments such that each segment includes the same arc length. In some embodiments, the processing region 227 is divided into equal sections in a plane parallel to the pedestal 247. Each segment of the processing region 227 corresponds to a segment of the heater ring 250. Each section of insulated material deposited in the heater ring 250 may be of any suitable arc length that provides sufficient insulation between adjacent segments of the heater ring 250. For example, each section of insulated material may have a width from 0.1 to 50 millimeters (mm).

To further control the temperature of the process chamber 100, cooling water may flow through the plurality of adapter plates 108, 123, 124 via water cooled elements 230. In some embodiments, the plurality of adapter plates 108, 123, 124 include a plurality of cooling water plenums to flow cooling water through. The plurality of cooling water plenums may fluidly couple to other components in the process chamber to supply cooling water that decreases the temperature of those components. The plurality of adapters 108, 123, 124 may each include a plurality of water cooled plenums within them such that the temperature of the chamber body 114 is lowered. The plurality of water cooled plenums may be disposed adjacent to the plurality of exhaust plenums 244 and plurality of delivery plenums 243 in order to cool the plurality of exhaust plenums 244 and plurality of delivery plenums 243.

Additionally, cooling water is flowed through the process chamber 100 in components outside of the processing region 227 to decrease the reactivity of the plasma and gases before they are in the processing region 227. If the plasma and gases are reactive before reaching the processing region 227, they may react with the materials of the channels and conduit they flow through and erode away the surfaces of these components. Accordingly, cooling water is flowed through these components such as the remote plasma source delivery plenums, top adapter plate 108, middle adapter plate 123, and lower adapter plate 124 to prevent the corrosion of these components.

The temperature of the chamber body 114 is desired to be lower to conserve the thermal budget of the process chamber 100. The process chamber 100 of the current disclosure is designed for plasma based deposition processes, such as PVD, as opposed to chemical vapor deposition (CVD) processes which operate at much higher temperatures. Through the use of selective heating of certain components of the process chamber 100 combined with running cooling water through the process chamber 100 and the overall lower process temperatures of the plasma based deposition processes allows the thermal budget of the process chamber 100 to be conserved. Constantly heating the process chamber 100 to a high temperature and then cooling the process chamber 100 to a much lower temperature runs through a thermal budget of a process chamber 100 and causes components of the process chamber 100 to break. Accordingly, it is necessary to heat only the processing region 227 of the process chamber 100, and specifically only the specific components in which the process gas or cleaning gas is desired to react with. For example, during a cleaning process, the shield 231 may be the only component of the process chamber 100 that is desired to be a reaction site because of the build up of deposited material on the surface of the shield 231. For example, the process kit 237 may be heated to a temperature from 200 to 300 degrees Celsius. Accordingly, in this example, only the shield 231 is heated, while the temperature of all other components of the process chamber 100 is decreased to decrease the reactivity on the surfaces of the other components.

Additionally, the temperature of the pedestal 247 may be controlled to control where cleaning occurs in the process chamber 100. To increase the reaction site selectivity of the pedestal 247, the temperature of the pedestal 247 may be increased via a pedestal heater 246. The pedestal heater 246 is positioned below the pedestal 247. The pedestal heater 246 may be coupled to a pedestal heater device (not shown) located outside of the process chamber 100. In some embodiments, the pedestal heater 246 is coupled to a pedestal heater device via a conduit run through a pedestal stem 236 and other components of the pedestal support. In some embodiments the pedestal heater 246 is a ceramic heater. The ceramic heater may have a ceramic heating element and may generate heat through resistive heating.

In some embodiments, the temperature of the pedestal 247 is decreased to lower the reaction site selectivity of the pedestal 247. The temperature of the pedestal 247 may be lowered in conjunction with increasing the temperature of the shield 231. In these embodiments, the cleaning gas is driven to react at the site of the shield 231 more than at the site of the pedestal 247. This reaction site selectivity control may be useful when more deposit material build up is observed on the shield 231 rather than the pedestal 247.

In some embodiments, the pedestal heater 246 may be segmented, such that each segment has its own heating element that may be heated to a temperature independent of the heating elements of the other segments of the pedestal heater 246. Each segment of the pedestal heater 246 corresponds to a section of the pedestal 247. In some embodiments, the processing region 227 is divided into equal sections in a plane parallel to the pedestal 247. In some embodiments, the processing region 227 is divided into 2 to 24 equal sections. Each segment of the processing region 227 corresponds to a segment of the pedestal heater 246. Accordingly, multiple sections of the pedestal 247 may each be heated to different temperatures, such that the reaction selectivity varies across the pedestal 247. Controlling the temperature, and accordingly the reaction site selectivity of the segments of the pedestal 247, may be useful when a pattern of deposition material build up is noticed after processing a batch of substrates. An operator of the process chamber 100 may observe a deposition material build up in certain sections rather than others. In response, different segments of the pedestal heater 246 may be variably heated such that the sections of the pedestal 247 with greater deposition material build up have an increased temperature in comparison to other sections of the pedestal 247.

In embodiments in which the pedestal heater 246 is segmented, the segments may be of equal area or different sized areas. For example, the pedestal heater 246 may be divided into four equal segments such that each segment includes the same area. In some embodiments, the pedestal 247 and pedestal heater 264 each have circular areas. In these embodiments, the pedestal heater 246 is divided into four sectors of the circular area of the pedestal heater 246. Each sector is defined by two radii and an arc along the circumference of the pedestal heater 246, the arc equal to one quarter of the circumference of the pedestal heater 246. It should be appreciated that other geometries may be considered and that the areas may be equally divided in other methods including, but not limited to, dividing the area of the pedestal heater 246 via various rectangular bands across the pedestal heater 246, each rectangular band of a different height so that each rectangular band has the same area.

In embodiments in which the pedestal heater 246 is segmented, insulated material may be deposited between each segment of the pedestal heater 246 such that no conductive material of one segment of the pedestal heater 246 directly contacts another segment of the pedestal heater 246. Each section of insulated material deposited in the pedestal heater 246 may be of any suitable width that provides sufficient insulation between adjacent segments of the pedestal heater 246. For example, each section of insulated material may have a width from 0.1 to 50 millimeters (mm).

FIG. 2 illustrates the shutter disk 232 in an activated position in which the shutter disk 232 is supported by a plurality of lift pins 233. The lift pins are coupled to a lift pin hoop 234 which can activate or deactivate the plurality of lift pins 233 in either an activated position or a deactivated position. In the activated position, the plurality of lift pins 233 contacts a lower surface of the shutter disk 232; whereas in the deactivated position, the plurality of lift pins 233 does not contact a lower surface of the shutter disk 232. The plurality of lift pins may be activated and deactivated via a pin lift actuating device.

The pedestal 247 may be actuated to raise and lower via a pedestal lift 219. The pedestal 247 is raised via a plurality of lift pins 233 extending through the pedestal 247. In some embodiments, the pedestal lift 219 is a long stroke pedestal lift. The pedestal 247 is coupled to the pedestal stem 236. The pedestal stem 236 extends through an opening in the bottom surface of the chamber body 114 into the processing region 227. The opening in the bottom surface of the chamber body 114 is of a greater diameter than the diameter of the pedestal stem 236. Circumscribing the opening in the bottom surface of the chamber body 114 is a debris sleeve 235. The debris sleeve 235 extends upwards into the processing region 227 and surrounds the pedestal stem 236. The pedestal stem 236 is coupled to a central opening flange 242 which restricts the upwards vertical movement of the pedestal stem 236. In some embodiments, the central opening flange 242 is coupled to the chamber body 114 for further support.

FIG. 3 illustrates an angled, schematic, cross-sectional view of a processing region 227, the plurality of delivery plenums 243, and the plurality of exhaust plenums 244 of a process chamber 100, according to one or more embodiments. The plurality of delivery plenums 243 provides a channel to deliver a fluid, including a liquid, gas, or plasma, to the processing region 227. The fluid exits the plurality of delivery plenums 243 to the processing region 227 via the plurality of upper ports 240. The plurality of upper ports 240 are positioned in the upper portion of the processing region 227. The plurality of upper ports 240 are positioned within the shield 231. The plurality of delivery plenums 243 are positioned within portions of the upper adapter plate 108 and the middle adapter plate 123. Further, each of the plurality of delivery plenums 243 are positioned within the shield 231 to connect with each of the corresponding upper ports 240. Each of the plurality of delivery plenums 243 are also connected to the remote plasma source delivery plenum 183.

The plurality of lower ports 245 are positioned in the lower portion of the processing region 227 to receive the fluid delivered into the processing region 227 by the plurality of upper ports 240. The fluid travels through the plurality of lower ports 245 to an exhaust chamber or other chamber component via the plurality of exhaust plenums 244 connected to the plurality of lower ports 245. The plurality of exhaust plenums 244 are positioned within portions of the middle adapter plate 123 and the lower adapter plate 124. Additionally, similar to the plurality of deliver plenums 243, the plurality of exhaust plenums are positioned within the shield 231 to connect with each of the corresponding lower ports 245. In some embodiments, the plurality of lower ports 245 are positioned within a recessed region of the shield 231. The upper edge of each of the plurality of lower ports 245 is positioned below the bottom surface of the pedestal 247 when the pedestal 247 is in a cleaning position. The lower ports 245 are positioned low in the process chamber so that the cleaning gas or plasma does not immediately exhaust through the lower ports 245 once the cleaning gas or plasma is delivered from the plurality of upper ports 240.

To assist in preventing the leakage of a cleaning gas or plasma to the lower portion of the processing region beneath the shield 231, the shield 231 forms a labyrinth 349 with a substrate support pedestal shield 341 coupled to the pedestal 247. The labyrinth 349 may be made of any suitable material. In some embodiments, the labyrinth 349 is made of a ceramic material or any other material with an increased resistance to fluorine.

The pedestal shield 341 is coupled to the upper surface of the pedestal 247 around the circumference of the pedestal 247. The pedestal shield 341 may include a plurality of shield ridges 357. A substrate may be disposed in the plurality of shield ridges 357 such that the substrate is more easily place in and removed from the pedestal shield 341 and pedestal 247.

In some embodiments, the pedestal shield 341 includes a shield wall 352. The shield wall 352 extends below the upper surface of the pedestal 247 and below the bottom surface of the shield 231. The shield wall 352 overhangs the edge of the pedestal 247 along the entire circumference of the pedestal 247 such that it provides a barrier to prevent a gas or plasma from contacting the inner components of the pedestal 247. A shield step 348 is coupled to the shield wall 352 and a shield extension 353 to form a J-shaped hook when viewing a cross-section of the labyrinth 349. The shield step 348 extends radially outwards towards the process kit 237. In some embodiments, the width of the shield step 348 is from about 0.1 inches to about 0.25 inches.

In some embodiments, the labyrinth 349 is sealed when the process kit edge 238 contacts the shield step 348. In some embodiments, the labyrinth 349 is sealed when the shield extension 353 contacts a bottom surface of the shield 231. In some embodiments, the bottom surface of the shield 231 is recessed and a cavity is formed defined by the process kit edge 238.

The ratio of the length of the shield wall 352 to the length of the shield step 348 may be sufficiently large to prevent the flow of the cleaning gas into the lower portion of the processing region 227. An increased ratio of the length of the shield wall 352 to the length of the shield step 348, in conjunction with the angle of entry of the cleaning gas into the processing region 227, decreases the likelihood of the cleaning gas flowing into the lower portion of the processing region. In some embodiments, the ratio of the length of the shield wall 352 to the length of the shield step 348 is from about 3:1 to about 25:1.

The shield 231 includes an overhang at a bottom surface of the shield 231 which includes a process kit recess 256. The shield extension 353 inserts into the process kit recess 256 of the shield 231 to prevent the flow of plasma or gas to the lower portion of the processing region 227 of the process chamber 100.

In some embodiments, a support ring 351 is positioned in the lower portion of the processing region 227 to provide stability to the heater ring 250. As seen in FIG. 3, the support ring 351 is positioned below the shield 231 and below an extension of the lower adapter plate 124. In some embodiments, the support ring 351 is positioned behind the heater ring 250.

In some embodiments, to assist in cleaning gas leakage detection, a detection ring 358 is positioned in the lower portion of the processing region 227. As seen in FIG. 3, the detection ring 358 is positioned below the heater ring 250. In some embodiments, the detection ring 358 is directly coupled to the heater ring 250. In some embodiments, the detection ring 358 is coupled to a different component in the lower portion of the processing region 227. In some embodiments in which it is desired to detect a cleaning gas leakage in the upper portion of the processing region 227, the detection ring 358 is coupled to a component in the upper portion of the processing region 227. The detection ring 358 may be made of a material that can withstand the higher temperatures of a deposition chamber and readily reacts with the cleaning gas used to clean the process chamber 100. In some embodiments, the cleaning gas used to clean the process chamber 100 is fluorine. In these embodiments, the detection ring 358 is made of titanium, so that the fluorine readily reacts with the titanium detection ring 358 rather than other components in the lower portion of the processing region 227. In some embodiments, the detection ring 358 is observed to detect a buildup of fluorine on the detection ring 358. In some embodiments, the detection ring 358 is observed to determine if a fluorine gas leakage has occurred by viewing the corrosion of the detection ring 358. In some embodiments, the detection ring 358 is sacrificial and may be removed from the process chamber 100 and replaced with a second detection ring 358 when the first detection ring 358 becomes too corroded.

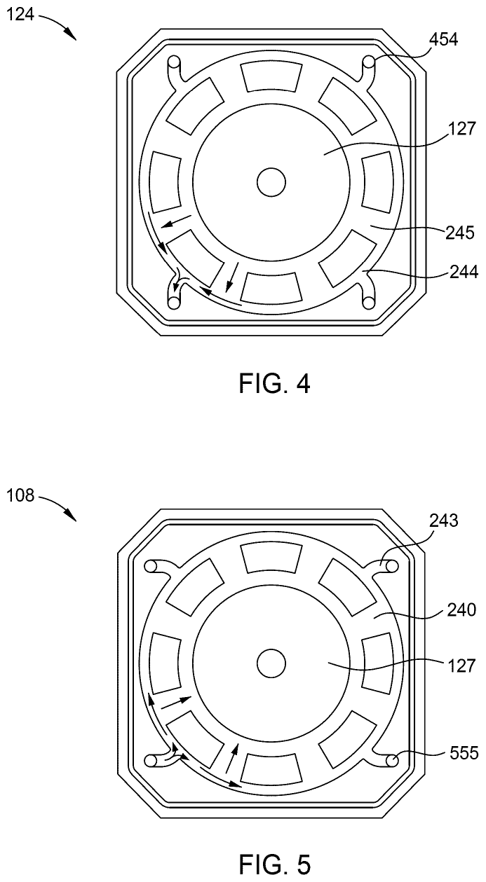

FIG. 4 illustrates a top view of the bottom adapter plate 124, according to one or more embodiments. The plurality of lower ports 245 are each coupled to a corresponding exhaust plenum outlet 454 via the exhaust plenums 244. In some embodiments, the exhaust plenums 244 form one continuous ring surrounding the processing region 227. Gases or plasma flow from the processing region 227, through the plurality of lower ports 245, through the exhaust plenums 244, and through the plurality of exhaust plenum outlets 454.

FIG. 5 illustrates a top view of the upper adapter plate 108, according to one or more embodiments. The plurality of upper ports 240 are each coupled to a corresponding delivery plenum inlet 555 via the delivery plenums 243. In some embodiments, the delivery plenums 243 form one continuous ring surrounding the processing region 227. Gases or plasma flow from the remote plasma source 101, through the remote plasma source delivery plenums 183, through the plurality of delivery plenum inlets 555, through the delivery plenums 243 positioned within the upper adapter plate 108, and through the upper ports 240 to the processing region 227. Each of the plurality of upper ports 240 are equally spaced from one another such that the gas or plasma delivery from each process inlet 240 is substantially equivalent. Further, the distance from each process inlet 240 and the corresponding delivery plenum inlet 555 is substantially equivalent so that the flow rate of the gas or plasma is substantially equivalent through each process inlet 240.

In some embodiments, there are eight upper ports 240 through which a plasma is delivered. The eight upper ports 240 are evenly spaced from one another along the circumference of the shield 231. In this embodiment, there are four delivery plenum inlets 555. Each delivery plenum inlet 555 corresponds to two of the eight upper ports 240. The distance between the delivery plenum inlet 555 and each of the corresponding upper ports 240 is the same. In this embodiment, there are also eight lower ports 245 and four exhaust plenum outlets 454. Each of the eight lower ports 245 are positioned directly below each of the eight upper ports 240. Each of the four delivery plenum inlets 555 are positioned directly below each of the four exhaust plenum outlets 454.

It should be appreciated that other configurations are equally acceptable and may achieve the same result of an equal flow rate of plasma or gas delivered to the processing region 227. For example, the number of upper ports 240 and lower ports 245 may be any number such that they are equally spaced throughout the shield 231. In some embodiments, the number of upper ports 240 is between 2 and 128. In some embodiments, the number of lower ports 245 is between 2 and 128.

Further, the number of upper ports 240 does not need to equal the number of lower ports 245. In some embodiments, there are 8 upper ports 240 and 4 lower ports 245. In some embodiments, there are 8 upper ports 240 and 16 lower ports 245.

In some embodiments, the lower ports 245 are not positioned directly below the upper ports 240. In some embodiments, the lower ports 245 may be staggered such that each process outlet 245 is positioned below the midline between adjacent upper ports 240. Additionally, in some embodiments, the exhaust plenum outlets 454 are not positioned directly below the delivery plenum inlets 555. For example, in some embodiments the exhaust plenum outlets 454 may be positioned in the corners of the lower adapter plate 124 and the delivery plenum inlets 555 are positioned in the centers of the edges of the upper adapter plate 108.

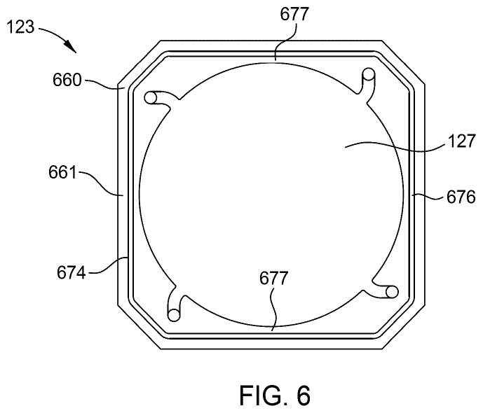

FIG. 6 illustrates a top view of the middle adapter plate 123, according to one or more embodiments. The middle adapter plate 123 includes an O-ring groove 660 in which an O-ring may be disposed. Each adapter plate 108, 123, 124 may include an O-ring groove to tighten the seal between the adapter plates while providing a secure connection. Additionally, the middle adapter plate 123 includes a plurality of purge delivery holes 661. Each of the purge delivery holes 661 may be located adjacent to the O-ring groove. The purge delivery holes 661 may be used to flow a purge gas into the processing region 227. The purge gas may include any suitable gas such as argon. Each adapter plate 108, 123, 124 may include a plurality of purge delivery holes 661.

Each adapter plate 108, 123, 124 may include a circumferential purge channel 674. In some embodiments, the circumferential purge channel 674 is positioned concentrically with the O-ring groove to allow an inert gas to flow into the processing region 227 while creating a back pressure that prevents the cleaning gas from exiting the processing region 227 during a cleaning process. The inert gas may be delivered via the plurality of purge delivery holes 661. Further, each adapter plate 108, 123, 124 may include a plurality of central purge grooves 676 and side purge grooves 677 to assist in the delivery of the inert gas to the processing region 227.

FIG. 7 illustrates a cross-sectional view of the processing region 227, delivery plenums 243, and exhaust plenums 244 of the process chamber 100, according to one or more embodiments. As seen from the cross-sectional view of the processing region 227, the delivery plenums 243 are located within the upper adapter plate 108 and the middle adapter plate 123. The exhaust plenums 244 are located within the lower adapter plate 124 and the middle adapter plate 123. The middle adapter plate 123 includes a barrier to separate the delivery plenums 243 from the exhaust plenums 244.

The delivery plenums 243 are also located within the shield 231. The delivery plenums 243 are angled upwards to direct the plasma or gas flowing through the delivery plenums 243 up towards the pedestal 247, walls of the shield 231, and other components in the upper portion of the processing region 227. It is desired to have an upward trajectory of the process gas or plasma so that the desired upper portion of the processing region 227 is cleaned. Further, the lower portion of the processing region 227 includes components that a cleaning gas or plasma may corrode. Adjusting the angle of the delivery plenums 243 is another method to direct the cleaning gas and plasma to specific parts of the process chamber 100. This method may be further combined with controlling the temperature of different areas of the process chamber 100, and blocking the flow of gas and plasma from the upper portion of the processing region 227 to the lower portion of the processing region 227 by implementing the labyrinth 349 separating the two portions.

The edges and corners of the delivery plenums 243 and the exhaust plenums 244 may be substantially curved to minimize the reactivity of the cleaning gas or plasma at these locations. For example, the edge of the delivery plenum 243 near the process outlets 245 may be substantially curved and recessed to prevent the cleaning gas or plasma from reacting with the material of the delivery plenums 243 or exhaust plenums.

Additionally, the diameter of the delivery plenums 243 or exhaust plenums may be increased in the corners or certain areas where the direction of the cleaning gas or plasma suddenly changes in an angle greater than 15 degrees. The increased diameter in these areas prevents fluorine from reacting with the material at these locations. In some embodiments, the angle of the delivery plenum 243 is angled to have an exit angle of greater than 15 degrees from the process inlet 240. The exit angle is measured from a plane substantially parallel to the middle adapter plate 123.

The width of each process inlet 240 or process outlet 245 may be substantially the same or different from one another as long as the same flow rate is produced from each process inlet 240 or process outlet 245. In some embodiments, the width of each process inlet 240 is from 2 to 40 millimeters (mm) and each of the upper ports 240 are the same width. In some embodiments, there are seven upper ports 240. In these embodiments, six of the upper ports 240 have the same width while one of the upper ports 240 has a different width that allows the one different width process inlet to deliver the same flow rate of gas or plasma to the processing region 227 as two of the six same sized upper ports 240 provide combined.

The height of each process inlet 240 or process outlet 245 may be substantially the same or different from one another as long as the same flow rate is produced from each process inlet 240 or process outlet 245. In some embodiments, the height of each process inlet 240 is from 0.5 to 20 mm. In some embodiments, the heights of each of the upper ports 240 may be different in configurations similar to those discussed above for varying widths of the upper ports 240.

It should be appreciated that similar methods may be utilized to alter the configurations, widths, and lengths of the lower ports 245 that are discussed to alter the configurations, widths, and lengths of the upper ports 240.

The ratio of the height of the process inlet 240 to the width of the process inlet 240 may be from 2:1 to 1:10. The ratio of the height of the process outlet 245 to the width of the process outlet 245 may be from 2:1 to 1:20. The ratio of the area of the process inlet 240 to the area of the process outlet 245 may be from 2:1 to 1:3.

The shape of the process inlet 240 may be an ellipsoid. In some embodiments, the height of the process inlet 240 is greater than the width of the process inlet 240. In some embodiments, the height of the process inlet 240 is less than the width of the process inlet 240. In some embodiments, the shape of the process inlet 240 may be a rectangle, circle, square, star, trapezoid, or other polygon. Different geometries may be used to increase the uniformity of the gas flow rate through the process inlet 240 as well as to prevent the deposition of the process gas or plasma on the edges of the process inlet 240. It should be appreciated that other geometries in manners similar to those disclosed above for the upper ports 240 may be applied to the lower ports 245.

FIG. 7 also illustrates gaps 772 between the shield 231 and the plurality of adapter plates 108, 123, 124. Gaps 772 exists between the shield 231 and plurality of adapter plates 108, 123, 124 to prevent the conductance of heat from the shield 231 to the plurality of adapter plates 108, 123, 124. Additionally, gaps 772 exist between the shield 231 and plurality of adapter plates 108, 123, 124 to provide space for the shield 231 to expand as it is heated to high temperatures for processing or cleaning.

However, the gaps 772 are not so large in the upper portion of the shield 231 and the target outer edge 773 that the gaps 772 would create dark spaces in which arcing could occur. Dark spaces are areas in which no plasma is generated during a PVD process. Dark space area may be defined by the annulus between the upper adapter plate 108 and the outer target edge 773. During deposition, the target 209 has a high electrical potential on the surface. There is a gap between the surface of the target 209 in which material is ejected from and the target outer edge 773 which positions the target 209 onto the process chamber 100. This gap is filled with the shield 231. However, as discussed above, a gap 772 exists between the shield 231 and the plurality of adapter plates 108, 123, 124, and accordingly the gap 772 exists between the shield 231 and the target outer edge 773 that is disposed directly over the upper adapter plate 108. If the gap 772 is too large, then arcing between the target outer edge 773 and the surface of the target 209 in which material is ejected from can occur. Accordingly, the gap 772 should be sufficiently large to allow for thermal expansion of the shield 231 and other components while still being small enough to minimize the risk of arcing.

In some embodiments, the shield 231 includes a plurality of spring elements to provide grounding and controlled thermal conductivity between the shield 231 and plurality of plate adapters 108, 123, 124. In some embodiments, the spring elements are coil springs.

FIG. 7 illustrates the various connections between the different components of the process chamber 100 in the processing region 227. For example, the lower adapter plate 124 is disposed over the chamber body 114. The chamber body 114 includes an O-ring 770 disposed in an O-ring groove 660A. The middle adapter plate 123 is disposed over the lower adapter plate 124. The lower adapter plate 124 includes an O-ring 770 disposed in an O-ring groove 660B. The upper adapter plate 108 is disposed over the middle adapter plate 123. The middle adapter plate 123 includes an O-ring 770 disposed in an O-ring groove 660C. The target 209 is disposed over portions of the shield 231 and the upper adapter plate 108. The upper adapter plate includes an O-ring 770 disposed in an O-ring groove 660D which provides a seal between the target 209 and the upper adapter plate 108, similar to the other O-rings 770 and O-ring grooves 660 referred to above.

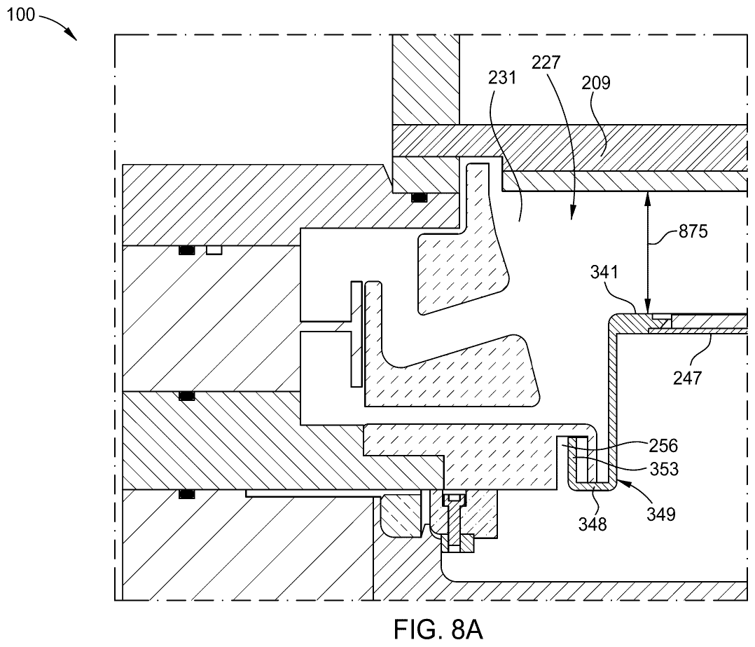

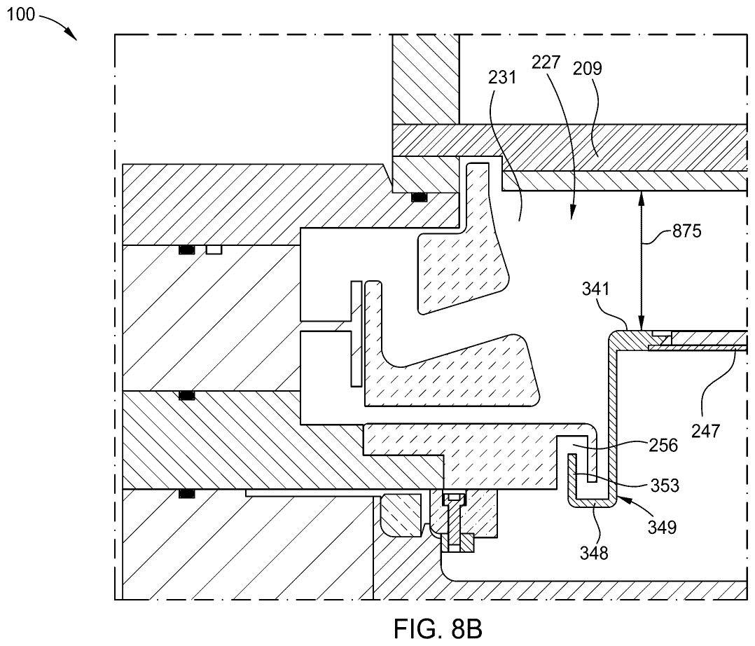

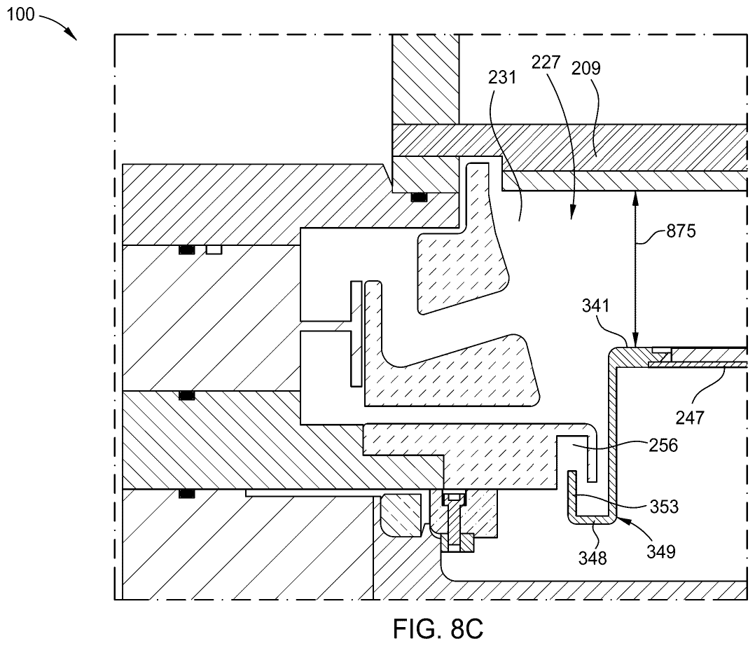

FIG. 8A illustrates a cross-sectional view of a processing region 227, wherein the process chamber 100 is in a cleaning position, according to one or more embodiments. The labyrinth 349 is substantially sealed by raising the pedestal 247. Accordingly, the shield extension 353 extends up into the process kit recess 256. The shield step 348 contacts the lower surface of the edge of the shield 231, creating a seal between the upper portion of the processing region 227 and the lower portion of the processing region 227. When a seal is created between the upper portion of the processing region 227 and the lower portion of the processing region 227, the process chamber 100 is in the cleaning position.

The cleaning position may be defined by the distance 875 between the upper surface of the pedestal shield 341 and the lower surface of the target 209. In some embodiments the distance 875 is from 50 to 55 mm, such as 52 mm or 53 mm.

FIG. 8B illustrates a cross-sectional view of the processing region 227, wherein the process chamber 100 is in a minimum deposition position, according to one or more embodiments. FIG. 8C illustrates a cross-sectional view of the processing region 227, wherein the process chamber 100 is in a maximum deposition position, according to one or more embodiments. The labyrinth 349 may be unsealed to enter a deposition position by lowering the pedestal 247. In a deposition position, the process chamber 100 may have a distance 875 between the upper surface of the pedestal shield 341 and the lower surface of the target 209 from 50 mm to 70 mm. The distance 875 between the upper surface of the pedestal shield 341 and the lower surface of the target 209 must be greater in the deposition position than in the cleaning position.

In some embodiments, the deposition position is defined as the ratio between the distance 875 and the overall height of the process chamber 100. For example, the ratio between the distance 875 and the overall height of the process chamber 100 is from 1:10 to 1:10,000. In any of the above embodiments, the deposition position is still defined by a lack of a seal between the upper portion of the processing region 227 and the lower portion of the processing region 227. In a deposition position, the upper portion of the processing region 227 should be in fluid connectivity with the lower portion of the processing region 227 via a gap in the labyrinth 349.

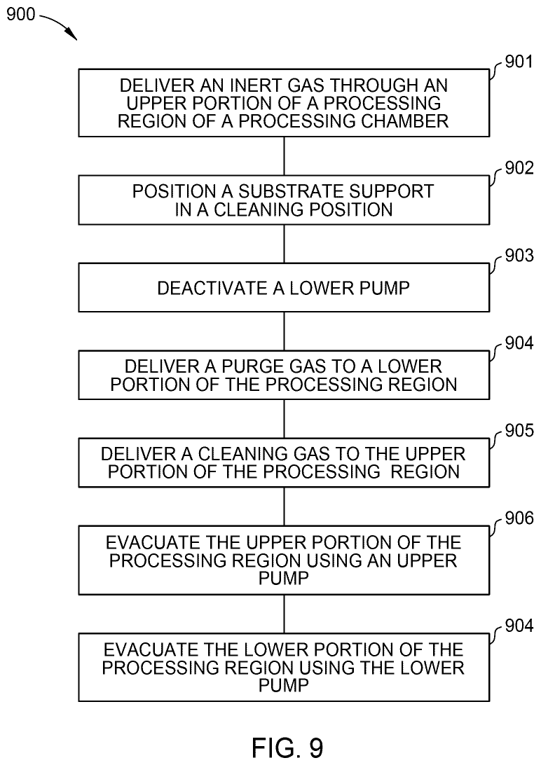

FIG. 9 illustrates a flow diagram of a method 900 of cleaning a process chamber 100, according to one or more embodiments. In these embodiments, a material deposited in the processing region 227 is removed from the processing region 227. In some embodiments, a material is deposited on a shield 231 in the upper portion of the processing region 227. The deposited material is then removed via the method 900.

At operation 901, an inert gas is delivered through the upper portion of the processing region 227 of the process chamber 100. In some embodiments, the inert gas is argon. The inert gas is delivered to purge the processing region 227 of any residual gases that may be present in the processing region from previous processing procedures.

At operation 902, the pedestal 247 is positioned in a cleaning position in which the labyrinth 349 forms a seal between the upper portion of the processing region 227 and the lower portion of the processing region 227. The pedestal 247 may be raised via the pedestal lift 219.

At operation 903, the lower pump 118 is deactivated. The lower pump 118 is fluidly coupled to the lower portion of the processing region 227. In some embodiments, the lower pump 118 is a turbo pump.

At operation 904, a purge gas is delivered to the lower portion of the processing region 227. In some embodiments, the purge gas is the same as the inert gas delivered through the upper portion of the processing region 227. In some embodiments, the purge gas is argon. The purge gas may be delivered to the lower portion of the processing region 227 via the plurality of chamber body gas inlets 115 that are fluidly coupled to the lower portion of the processing region 227.

The purge gas is delivered to the lower portion of the processing region 227 to create a backpressure on the labyrinth 349 such that the cleaning gas later delivered will not leak through the labyrinth into the lower portion of the processing region 227.

At operation 905, the cleaning gas is delivered to the upper portion of the processing region 227. The cleaning gas may be any suitable cleaning gas that will remove the deposited material that is built up in the processing region 227. The cleaning gas may be delivered as a gas or a plasma. In some embodiments, a fluorine plasma is delivered to the processing region 227 to clean deposited material built up on components in the processing region 227.

The cleaning gas may be a plasma generated at the remote plasma source 101. The plasma may then flow through the remote plasma source plenums 183, through the delivery plenums 243, and out through the plurality of lower ports 245 into the processing region 227. The angle of the delivery plenums 243 near the lower ports 245 may be angled such that the plasma is delivered in an upward angle towards the upper surfaces of the processing region 227.

The plasma delivered to the processing region 227 reacts with the deposited material that is built up on the surfaces of the shield 231, pedestal 247, and other components of the processing region 227. As discussed above, the temperature of various components of the processing region 227 may be controlled to control the reaction site selectivity of the plasma delivered to the processing region 227. The plasma will more likely react with the surfaces of components with a higher temperature. Accordingly, to remove a greater amount of deposited material built up in the shield 231, the temperature of the shield 231 will be increased. The temperature of the shield 231 may be increased via the heater ring 250.

In some embodiments, the operation of heating up the shield 231 occurs before the cleaning gas is delivered to the upper portion of the processing region 227 at operation 905. However, the operation of heating up the shield 231, or any other desired component, may occur simultaneously with the delivery of the cleaning gas to the processing region 227.

In one embodiment, a method of uniformly depositing a material on the substrate is contemplated. The method includes depositing a material on a sample wafer. The film thickness of the sample wafer is measured. Then areas of non-uniform deposition are observed. Before the next batch of wafers is processed, the temperature of the distinct areas of the pedestal are heated to increase the reaction site selectivity corresponding to areas of the sample wafer that experienced less deposition than other areas of the sample wafer. Distinct areas of the pedestal 247 may be heated in methods disclosed above when discussing using the pedestal heater 246 to individually heat different sections of the pedestal 247.

It should also be appreciated that during any of the operations listed, a cooling water may flow through the process chamber 100 to maintain a low temperature of components in the process chamber 100. Components at a lower temperature do not readily react with the cleaning gas or plasma flowed through the process chamber 100. Accordingly, these components are kept at a lower temperature to increase the efficiency of the cleaning gas in only reacting with the deposited material built up in the processing region 227.

Once the cleaning gas has reacted with the deposited material built up on the surfaces of the processing region 227, the cleaning gas may exit the processing region 227 via the plurality of lower ports 245 positioned below the plurality of upper ports 240. The cleaning gas may exit the processing region either as the initial cleaning gas delivered, i.e., fluorine, or it may exit as a compound containing the elements of deposited material that it reacted with to clean off of the surfaces of the processing region 227.

At operation 906, the upper portion of the processing region 227 is evacuated using the upper pump 117. The upper portion of the processing region 227 is evacuated to remove any cleaning gas from the upper portion of the processing region 227 before the next series of deposition processes occurs. The upper pump 117 is fluidly coupled to the upper portion of the processing region 227. In some embodiments, the upper pump 117 is a rough pump. The upper pump 117 is isolated from the lower portion of the processing region 227 when the pedestal 247 is in the cleaning position. Similarly, the lower pump 118 is isolated from the upper portion of the processing region 227 when the pedestal 247 is in the cleaning position.

At operation 907, the lower portion of the processing region 227 is evacuated using the lower pump 118. The lower portion of the processing region 227 is evacuated to remove any cleaning gas from the lower portion of the processing region 227 before the next series of deposition processes occurs.

The above method discloses delivering a cleaning gas to the processing region 227 via the upper ports 240 and removing the cleaning gas from the processing region 227 via the lower ports 245. However, in some embodiments the cleaning gas is delivered to the processing region 227 via the lower ports 245 and the cleaning gas is removed from the processing region 227 via the upper ports 240. In these embodiments, the lower ports 245 are fluidly coupled to the remote plasma source delivery plenums 183.

Other methods of cleaning the shield 231 may include an initial operation of detecting an amount of material to be removed in each of two or more sections of the shield 231. In some embodiments, the amount of material to be removed from the shield 231 is determined by physical observation, such as looking into the process chamber, or is determined by a calculation that determines an amount of material to remove based on the amount of material delivered to the processing region 227. To clean the chamber, the shield 231 may be divided into two or more equal regions.

A cleaning temperature is determined for each region of the shield 231. A higher cleaning temperature correlates to a greater amount of material to remove from the shield 231. A higher cleaning temperature in one section of the shield 231 increases the reaction site selectivity of that section of the shield 231 versus other sections of the shield 231.

Each section of the shield 231 is heated to its correlated cleaning temperature. Each section of the shield 231 may be heated via any suitable heating means. In some embodiments, each section of the shield 231 is heated by a heater ring 250 disposed under the shield 231. In these embodiments, the heater ring 250 is segmented such that each segment of the heater ring 250 corresponds to each section of the shield 231. For example, if the heater ring 250 is divided into four segments, each segment corresponds to one of four sections of the shield 231.

After the shield 231 is heated, a cleaning gas is delivered to the processing region 227 defined by the shield 231. The cleaning gas may be delivered by any suitable means including via a remote plasma source 101.

Any one or more components of the various embodiments disclosed herein may be integrally formed together, directly coupled together, and/or indirectly coupled together and are not limited to the specific arrangement of components illustrated in FIGS. 1A-9. Any one or more of the components, embodiments, or steps of the embodiments disclosed herein may be combined in whole or part with any other components, embodiments, or steps of the embodiments disclosed herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits, and ranges appear in one or more claims below.

Certain embodiments and features have been described using the term “about” with a numerical value. When the term “about” is used in conjunction with a numerical value, it should be construed as indicating any numerical value within 10% of the stated numerical value.

While the foregoing is directed to embodiments of the present disclosure, other and further embodiments of the disclosure may be devised without departing from the basic scope thereof, and the scope thereof is determined by the claims that follow.

What is claimed is:

1. A process chamber, comprising:
a processing region defined by a target and a process kit, the process kit isolating a lower portion of the processing region from an upper portion of the processing region when the process chamber is in a cleaning position and the process kit comprising:
a shield;
a plurality of upper ports disposed on a surface of the shield;
a plurality of lower ports disposed on the surface of the shield, each lower port positioned below each of the plurality of upper ports;
an adapter plate;
a plurality of delivery plenums disposed within the adapter plate and shield, each delivery plenum of the plurality of delivery plenums forming a passageway from the adapter plate to one of the plurality of upper ports;
a plurality of exhaust plenums disposed within the adapter plate and shield, each exhaust plenum of the plurality of exhaust plenums forming a passageway from one of the plurality of lower ports to the adapter plate;
a plurality of water-cooled plenums within the adapter plate, each of the water-cooled plenums adjacent to the plurality of exhaust plenums and the plurality of delivery plenums; and
an edge including a recess in which a pedestal shield inserts into to form a labyrinth;
a heater ring positioned below and coupled to the process kit; and
a pedestal disposed in the processing region, the pedestal including the pedestal shield.

2. The process chamber of claim 1, further comprising a fluorine detection ring positioned below the process kit in a lower processing region and separating portions of a chamber body from the lower portion of the processing region.

3. The process chamber of claim 1, wherein the pedestal shield includes a shield wall extending into the lower portion of the processing region and a shield step extending radially outwards.

4. The process chamber of claim 3, wherein a ratio of a length of the shield wall to a length of the shield step is from about 3:1 to about 8:1.

5. The process chamber of claim 1, wherein the process chamber comprises two or more upper ports and two or more lower ports, and the processing region is divided into equal sections in a plane parallel to the upper surface of the pedestal.

6. The process chamber of claim 5, wherein the processing region is divided into 3-24 equal sections, wherein each section comprises one upper port and one lower port.

7. The process chamber of claim 1, wherein a lid of the process chamber is coupled to the process chamber via a hinge to allow the processing region to be accessed for service.

8. The process chamber of claim 1, further comprising:
an upper pump coupled to the upper portion of the processing region and isolated from the lower portion of the processing region when the pedestal is in a cleaning position; and
a lower pump coupled to the lower portion of the processing region and isolated from the upper portion of the processing region when the pedestal is in a cleaning position.

9. The process chamber of claim 8, wherein the upper pump is a rough pump or a turbo pump and the lower pump is a rough pump or a turbo pump.

10. The process chamber of claim 1, wherein the one or more delivery plenums is angled to have an exit angle of greater than 15 degrees from the upper ports.

11. The process chamber of claim 1, wherein the one or more delivery plenums include curved corners to prevent a build up of material in the curved corners.

12. The process chamber of claim 1, wherein there are two or more lower ports and wherein the two or more lower ports are configured so that a mass flow rate of cleaning gas flowing through each of the two or more lower ports is the same.

13. The process chamber of claim 1, wherein the target is positioned near an upper surface of the process kit and coupled to a lid of the process chamber, the target is coupled to an upper portion of the adapter plate via an outer target edge.

14. The process chamber of claim 1, further comprising a dark space area defined by the annulus between the upper portion of the adapter plate and the target outer edge.

15. The process chamber of claim 1, wherein a gap exists between the shield and the adapter plate by a radial distance from about 1 millimeter to 2 millimeters when the temperature of the pedestal is less than 350 degrees Celsius.

16. A process chamber, comprising:
a remote plasma source for generating a plasma;
a processing region comprising:
a pedestal;
a pedestal shield; and
a process kit defining an upper portion of the processing region and isolating the upper portion of the processing region from a lower portion of the processing region when the pedestal is in a cleaning position, the process kit comprising:
a shield;
the pedestal shield;
a shutter disk coupled to the pedestal; and
one or more adapter plates;
a plurality of remote plasma source delivery plenums coupled to the remote plasma source, the plurality of remote plasma source delivery plenums configured to deliver the plasma to the processing region;
a target comprising a material to be deposited on a substrate disposed on the pedestal, the substrate positioned in the upper portion of the processing region;
an upper pump fluidly coupled to the upper portion of the processing region and isolated from the lower portion of the processing region when the pedestal is in the cleaning position; and
a lower pump fluidly coupled to the lower portion of the processing region and isolated from the upper portion of the processing region when the pedestal is in the cleaning position.

17. The process chamber of claim 16, wherein a heater ring is coupled to the process kit.

18. The process chamber of claim 17, wherein the heater ring is configured to heat each section of the processing region individually to a distinct section temperature by distinct sections of the heater ring.

19. The process chamber of claim 18, wherein the heater ring is made of a nickel alloy or aluminum.

20. The process chamber of claim 16, wherein the one or more adapter plates comprise a top adapter plate, a middle adapter plate, and a bottom adapter plate.
